(19) United States
(12) Patent Application Publication
(10) Pub. No.: US 2026/0123400 A1
(43) Pub. Date: Apr. 30, 2026

(54) SEMICONDUCTOR STRUCTURE AND MANUFACTURING METHOD THEREFOR

(71) Applicant: CXMT Corporation, Hefei (CN)

(72) Inventors: Jun Chen, Hefei (CN); Lien-kuan Lin, Hefei (CN); Tzung-han Lee, Hefei (CN); Chunyang Wang, Hefei (CN)

(73) Assignee: CXMT Corporation, Hefei (CN)

(21) Appl. No.: 19/235,810

(22) Filed: Jun. 12, 2025

Related U.S. Application Data
(63) Continuation of application No. PCT/CN2025/080727, filed on Mar. 5, 2025.

(30) Foreign Application Priority Data
Oct. 30, 2024 (CN) 202411538521.2

(51) Int. Cl. H01L 23/522; H01L 21/768; H01L 23/498; H01L 23/528; H10D 1/00; H10D 1/68

(52) U.S. Cl. CPC H10W 20/496; H10W 20/056; H10W 20/427; H10W 20/43; H10W 20/435; H10W 20/498; H10W 70/635; H10D 1/041; H10D 1/716

(57) ABSTRACT

Disclosed a semiconductor structure includes: a substrate, including a device layer, a buried power rail, and a through silicon via, where the through silicon via is connected to the device layer through the buried power rail; a power network layer, disposed on the substrate, where the power network layer includes at least one layer of a first power array and at least one layer of a second power array, and each of the at least one layer of the first power array is connected to the buried power rail through the through silicon via; and a capacitor structure, disposed between each of the at least one layer of the first power array and each of the at least one layer of the second power array and connected to the first power array and the second power array through a lower electrode and an upper electrode of the capacitor structure respectively.

### CROSS-REFERENCE

This application is a continuation of International Patent Application No. PCT/CN2025/080727, filed on Mar. 5, 2025, which claims the benefit of Chinese Patent Application No. 202411538521.2, titled “SEMICONDUCTOR STRUCTURE AND MANUFACTURING METHOD THEREFOR”, filed with the China National Intellectual Property Administration (CNIPA) on Oct. 30, 2024, the disclosures of which are incorporated herein by reference in their entireties.

### TECHNICAL FIELD

Embodiments of the present disclosure relate to the field of semiconductors, and in particular, to a semiconductor structure and a manufacturing method therefor.

### BACKGROUND

In conventional chip fabrication and advanced 2.5D or 3D packaging, wiring is generally provided on the front side of a wafer, with signal lines and power lines vertically stacked and connected, to form a semiconductor device including an active electronic component with a multi-layer metal interconnection structure in an integrated circuit. In this approach, there are a signal interconnect network formed by signal lines and a power delivery network in the front region of a chip, and therefore it is difficult to further reduce the volume of the whole package structure. In view of this, a chip structure with a backside power delivery network (BSPDN) is proposed to overcome the drawback of a front-side power delivery structure. However, new problems such as high chip power consumption caused by an voltage drop due to the limitation of a power delivery path appear. How to further optimize the chip structure based on the backside power delivery technology and shorten the power delivery path to improve the device performance has become an urgent problem to be solved.

### SUMMARY

According to some embodiments of the present disclosure, an aspect of the embodiments of the present disclosure provides a semiconductor structure, including:
a substrate, including a device layer, a buried power rail, and a through silicon via, where the through silicon via is connected to the device layer through the buried power rail;
a power network layer, disposed on the substrate, where the power network layer includes at least one layer of a first power array and at least one layer of a second power array, and each of the at least one layer of the first power array is connected to the buried power rail through the through silicon via; and
a capacitor structure, disposed between each of the at least one layer of the first power array and each of the at least one layer of the second power array and connected to the first power array and the second power array through a lower electrode and an upper electrode of the capacitor structure respectively.

According to some embodiments of the present disclosure, another aspect of the embodiments of the present disclosure further provides a method for manufacturing a semiconductor structure, including:
providing a substrate, where a device layer, a buried power rail, and a through silicon via are formed within the substrate, and the through silicon via is connected to the device layer through the buried power rail; and
forming a power network layer and a capacitor structure on the substrate, where the power network layer includes at least one layer of a first power array and at least one layer of a second power array, each of the at least one layer of the first power array is connected to the buried power rail through the through silicon via, and the capacitor structure is formed between each of the at least one layer of the first power array and each of the at least one layer of the second power array and connected to the first power array and the second power array through a lower electrode and an upper electrode of the capacitor structure respectively.

The technical solutions provided according to the embodiments of the present disclosure at least have the following advantages:

According to the embodiments of the present disclosure, the capacitor structure is integrated into an internal part of the power delivery network, and the voltage stabilization can be improved without adding an additional capacitor structure, such that the volume of a chip is reduced; moreover, as the internal part of the power network can be directly connected to the capacitor structure, a power delivery path is shortened, such that the transmission resistance is reduced, and the stability and reliability of the power network are further enhanced.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a top view of a power network layer according to an embodiment of the present disclosure;

FIG. 2 is a cross-sectional view of a portion of a semiconductor structure along a direction AA′ in FIG. 1 according to an embodiment of the present disclosure;

FIG. 3 is a flowchart of a method for manufacturing a semiconductor according to an embodiment of the present disclosure;

FIG. 4 is another flowchart of a method for manufacturing a semiconductor according to an embodiment of the present disclosure;

FIG. 5 is still another flowchart of a method for manufacturing a semiconductor according to an embodiment of the present disclosure; and

FIG. 6 to FIG. 13 are cross-sectional views of a portion of a semiconductor structure along a direction AA′ in FIG. 1 corresponding to various steps in a method for manufacturing a semiconductor according to an embodiment of the present disclosure.

### DESCRIPTION OF EMBODIMENTS

Embodiments of the present disclosure are described in detail below with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments.

As an approach of chip design, by moving power lines to the back side of a wafer, a backside power delivery network (BSPDN) aims to solve the problems of RC (parasitic resistance and parasitic capacitance) bottlenecks and wire congestion caused by interconnect resources shared by signal lines and power lines in conventional front-side wiring. This approach not only eliminates the power rail requirements on the front side, but also allows for more economical strategies for interconnect scaling, and therefore costs can be reduced. However, the introduction of BSPDN also brings new challenges, most notably, the voltage drop effect due to the limitation of a power delivery path, which increases the power consumption of a chip and affects the overall performance.

To solve the foregoing technical problem, the embodiments of the present disclosure provide a semiconductor structure. The semiconductor structure provided according to the embodiments of the present disclosure will be described below with reference to the drawings.

FIG. 1 is a top view of a power network layer according to an embodiment of the present disclosure; and FIG. 2 is a cross-sectional view of a portion of a semiconductor structure along a direction AA′ in FIG. 1 according to an embodiment of the present disclosure. The semiconductor structure according to this embodiment of the present disclosure is described in detail below with reference to the drawings.

Referring to FIG. 1 and FIG. 2, a semiconductor structure 10 includes: a substrate 101, including a device layer 103, a buried power rail BPR, and a through silicon via 102, where the through silicon via 102 is connected to the device layer 103 through the buried power rail BPR; a power network layer 104, disposed on the substrate 101, where the power network layer 104 includes at least one layer of a first power array 1041 and at least one layer of a second power array 1042, and each of the at least one layer of the first power array 1041 is connected to the buried power rail BPR through the through silicon via 102; and a capacitor structure 108, disposed between each of the at least one layer of the first power array 1041 and each of the at least one layer of the second power array 1042 and connected to the first power array 1041 and the second power array 1042 through a lower electrode 1081 and an upper electrode 1084 of the capacitor structure 108 respectively.

In some embodiments, the material of the substrate 101 may be monocrystalline silicon (Si), monocrystalline germanium (Ge), silicon germanium (GeSi), or silicon carbide (SiC), or may be silicon-on-insulator (SOI) or germanium-on-insulator (GOI), or may also be another material, for example, a group III-V compound, for example, gallium arsenide. The substrate 101 may further include the device layer 103 configured to form a chip device, and the device layer 103 may include an active device, for example, a transistor or a diode; or a passive device, for example, a capacitor, an inductor, a resistor, and the like. A signal interconnect layer SL may further be provided below the device layer 103, and configured to connect the device layer 103 to an external control signal or an input/output signal. The buried power rail BPR may further be disposed within the substrate 101 as an interconnect line to which a power supply voltage or a grounding voltage is applied.

In some embodiments, referring to FIG. 1 and FIG. 2, the first power array 1041 extends along a first direction Y, the second power array extends along a second direction X, the first direction Y and the second direction X intersect in a direction parallel to the substrate 101, and projections of the first power array 1041 and the second power array 1042 in a direction perpendicular to the substrate 101 share overlapped portions. The angle formed by the intersection of the first direction Y and the second direction X in the direction parallel to the substrate 101 may be set to be a right angle, or other angles as needed. This is not limited herein. Illustratively, the power network layer 104 may include at least one first power array 1041 and at least one second power array 1042, and planes on which different power arrays are located are all parallel to the substrate 101 and are located at different layers. In this embodiment, the second power array 1042 may be disposed above the first power array 1041, and the projections of the first power array 1041 and the second power array 1042 in the direction perpendicular to the substrate 101 share the overlapped portion.

In some embodiments, referring to FIG. 1 and FIG. 2, the first power array 1041 and the second power array 1042 each include at least two power lines Vdd and at least two ground lines Vss. The at least two power lines Vdd and the at least two ground lines Vss of the first power array 1041 are parallel to one another and staggered along the second direction X, and the at least two power lines Vdd and the at least two ground lines Vss of the second power array 1042 are parallel to one another and staggered along the first direction Y. Illustratively, in a direction parallel to the substrate 101, the first power array 1041 includes a plurality of power lines Vdd and a plurality of ground lines Vss, where each of the power lines Vdd and each of the ground lines Vss are staggered along the second direction X; and the second power array 1042 further includes a plurality of power lines Vdd and a plurality of ground lines Vss, where each of the power lines Vdd and each of the ground lines Vss are staggered along the first direction Y. That is, the plurality of power lines Vdd and the plurality of ground lines Vss of the first power array 1041 and the plurality of power lines Vdd and the plurality of ground lines Vss of the second power array 1042 are perpendicular to one another, and projections in the direction perpendicular to the substrate 101 share overlapped portions. The power lines Vdd and the ground lines Vss of the first power array 1041 and the power lines Vdd and the ground lines Vss of the second power array 1042 are arranged at different layers, and the power lines Vdd and the ground lines Vss at each layer are staggered, to reduce voltage drop and signal interference between the power lines Vdd and the ground lines Vss, thereby improving the performance and reliability of circuits. The first power array 1041 is disposed in an isolation layer 105, and the material of the isolation layer 105 may be silicon oxide (SiO₂) for isolating the power line Vdd and the ground line Vss that are adjacent to one another.

In some embodiments, the shapes of the power lines Vdd and the ground lines Vss may be set to rectangular, square, circular, polygonal, serpentine, star-like, or others as needed. This is not limited herein. Illustratively, the power lines Vdd and the ground lines Vss are designed to be rectangular or square, to provide a large-area low impedance path, helping reduce voltage drop and electromagnetic interference; or may be designed to be serpentine as required. Serpentine curves can increase the wiring length by changing the direction of the wiring, helping match the length of a signal line and improving the signal integrity.

In some embodiments, still referring to FIG. 1 and FIG. 2, the overlapped portions of the projections of the first power array 1041 and the second power array 1042 in the direction perpendicular to the substrate 101 includes at least one first region I and at least one second region II. The at least one first region I includes overlapped portions of projections of the power lines Vdd of the first power array 1041 and the power lines Vdd of the second power array 1042 in the direction perpendicular to the substrate 101 and overlapped portions of projections of the ground lines Vss of the first power array 1041 and the ground lines Vss of the second power array 1042 in the direction perpendicular to the substrate 101; and the at least one second region II includes overlapped portions of projections of the ground lines Vss of the first power array 1041 and the power lines Vdd of the second power array 1042 in the direction perpendicular to the substrate 101 and overlapped portions of projections of the power lines Vdd of the first power array 1041 and the ground lines Vss of the second power array 1042 in the direction perpendicular to the substrate 101. Illustratively, referring to FIG. 1, the at least one first region I and the at least one second region II are staggered along both the first direction Y and the second direction X. That is, the at least one first region I and the at least one second region II are adjacent to one another in the first direction Y and the second direction X, and the area of each of the at least one first region I and the area of each of the at least one second region II may be the same or different along the direction parallel to the substrate 101.

In some embodiments, referring to FIG. 1 and FIG. 2, a contact plug CT is further provided between the first power array 1041 and the second power array 1042. The contact plug CT is disposed in each of the at least one first region I and configured to connect each of the power lines Vdd of the first power array 1041 to each of the power lines Vdd of the second power array 1042, or connect each of the ground lines Vss of the first power array 1041 to each of the ground lines Vss of the second power array 1042.

In some embodiments, the shape of the contact plug CT may be set to rectangular, square, circular, polygonal, star-like, or others as needed. This is not limited herein. The quantity of contact plugs CTs may be set to an integer number, for example, 1, 2, 3, . . . , or 10, as needed. This is not limited herein. The material of the contact plug CT includes, but is not limited to, one or more of copper (Cu), nickel (Ni), cobalt (Co), tungsten (W), titanium (Ti), tin (Sn), or an alloy thereof. In some embodiments, referring to FIG. 1 and FIG. 2, the capacitor structure 108 is disposed in each of the at least one second region II, the lower electrode 1081 of the capacitor structure 108 is connected to each of the power lines Vdd of the first power array 1041, and the upper electrode 1084 of the capacitor structure 108 is connected to each of the ground lines Vss of the second power array 1042; or the lower electrode 1081 of the capacitor structure 108 is connected to each of the ground lines Vss of the first power array 1041, and the upper electrode 1084 of the capacitor structure 108 is connected to each of the power lines Vdd of the second power array 1042. Illustratively, the second power array 1042, the capacitor structure 108, and the contact plug CT are all disposed in an insulating layer 106. The insulating layer 106 includes a first blocking layer 1061, a first insulating layer 1062, a second blocking layer 1063, and a second insulating layer 1064 and is configured to isolate and support the second power array 1042, the capacitor structure 108, and the contact plug CT. The materials of the first blocking layer 1061 and the second blocking layer 1063 may include silicon nitride (SiN), and the materials of the first insulating layer 1062 and the second insulating layer 1063 may include silicon oxide (SiO₂). The capacitor structure 108 includes the lower electrode 1081, a dielectric layer 1082, a barrier layer 1083, and the upper electrode 1084 sequentially stacked from bottom to top. The materials of the lower electrode 1081 and the upper electrode 1084 of the capacitor structure 108 may include cobalt (Co), titanium (Ti), nickel (Ni), tungsten (W), and molybdenum (Mo), metal nitride (for example, one or more of titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), and tungsten nitride (WN)). The material of the dielectric layer 1082 may include metal oxide (for example, one or more of HfO₂, ZrO₂, Al₂O₃, La₂O₃, Ta₂O₃, and TiO₂), and may have a single-layer structure or a multi-layer structure. The barrier layer 1083 may include metal nitrides, for example, one or more of titanium nitride (TiN), titanium silicon nitride (TiSiN), titanium aluminum nitride (TiAlN), and tantalum nitride (TaN), tantalum silicon nitride (TaSiN), tantalum aluminum nitride (TaAlN), and tungsten nitride (WN).

The capacitor structure 108 is integrated into an internal part of the power delivery network layer 104, and the voltage stabilization can be improved without adding an additional capacitor structure, such that the volume of the semiconductor structure is reduced; moreover, as the internal part of the power network 104 can be directly connected to the capacitor structure 108, a power delivery path is shortened, such that the transmission resistance is reduced, and the stability and reliability of the power network are further enhanced.

In some embodiments, referring to FIG. 1 and FIG. 2, the power lines Vdd and the ground lines Vss of the first power array 1041 are of the same quantity, and the power lines Vdd and the ground lines Vss of the second power array 1042 are of the same quantity, to keep the circuit balance and ensure that the current between the power lines Vdd and the ground lines Vss is uniformly distributed, thereby reducing voltage drop and signal interference and helping maintain the stability and reliability of a circuit.

In some embodiments, referring to FIG. 1 and FIG. 2, the distance W1 between each of the power lines Vdd and each of the ground lines Vss that are adjacent to one another ranges from 0.1 μm to 1.5 μm, helping reduce the size of a circuit and avoid crosstalk between the power lines Vdd and the ground lines Vss, thereby achieving optimal performance and cost balance of the semiconductor structure 10.

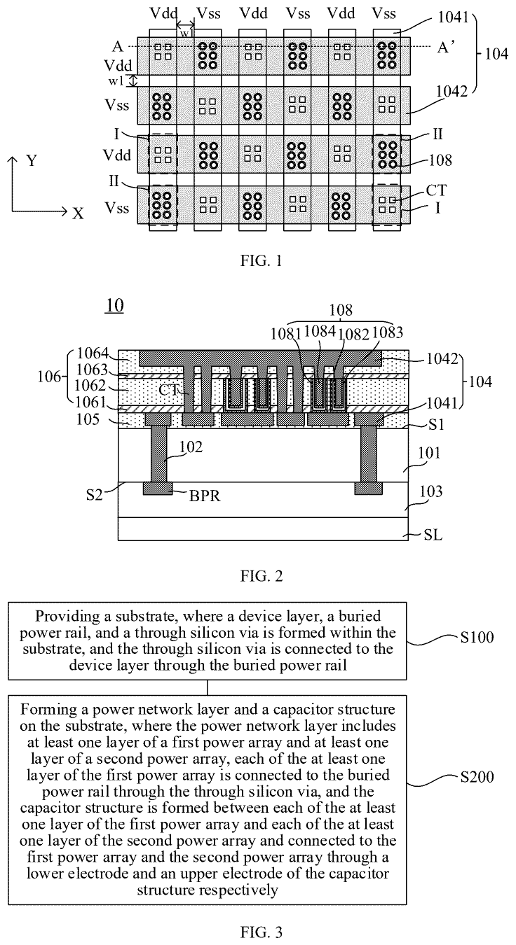

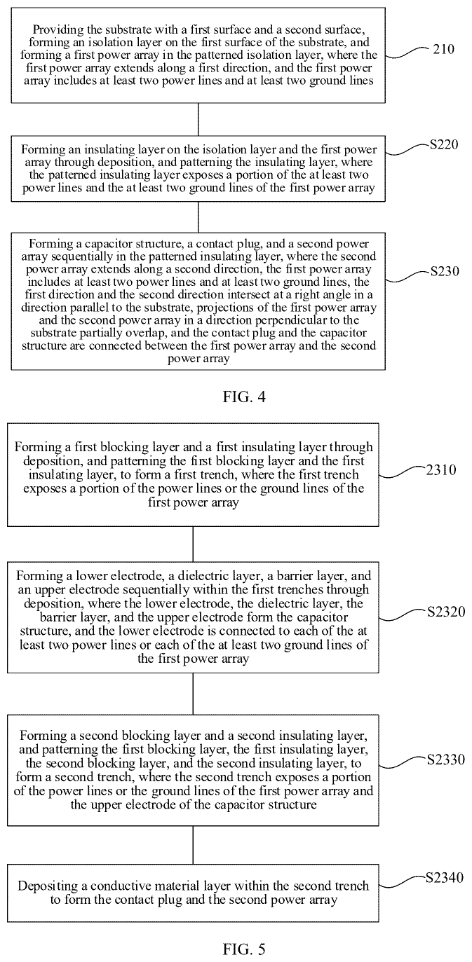

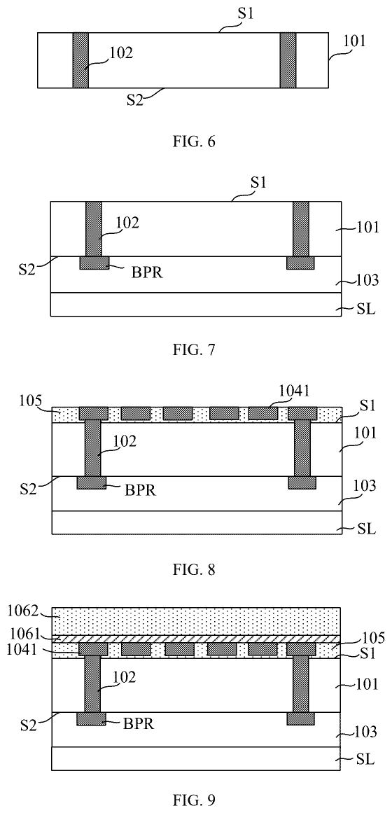

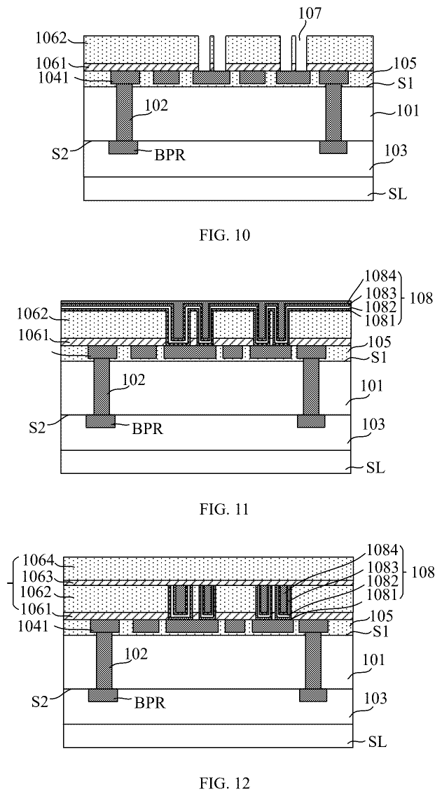

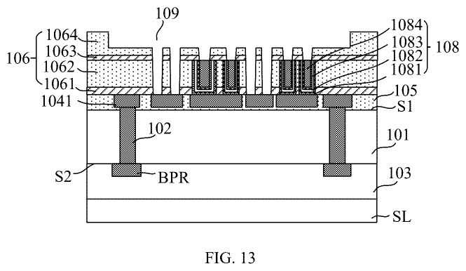

Accordingly, another embodiment of the present disclosure provides a method for manufacturing a semiconductor structure. FIG. 3 is a flowchart of a method for manufacturing a semiconductor according to an embodiment of the present disclosure; FIG. 4 is another flowchart of a method for manufacturing a semiconductor according to an embodiment of the present disclosure; FIG. 5 is still another flowchart of a method for manufacturing a semiconductor according to an embodiment of the present disclosure; and FIG. 6 to FIG. 13 are cross-sectional views of a portion of a semiconductor structure along a direction AA′ in FIG. 1 corresponding to various steps in a method for manufacturing a semiconductor according to an embodiment of the present disclosure. The method for manufacturing the semiconductor structure according to this embodiment of the present disclosure is described in detail below with reference to the drawings.

Referring to FIG. 3, an embodiment of the present disclosure provides a method for manufacturing a semiconductor structure 10. The method includes:

In S100, a substrate 101 is provided, where a device layer 103, a buried power rail BPR, and a through silicon via 102 are formed within the substrate 101, and the through silicon via 102 is connected to the device layer 103 through the buried power rail BPR.

In some embodiments, referring to FIG. 6 and FIG. 7, forming the device layer 103, the buried power rail BPR, and the through silicon via 102 within the substrate 101 includes: forming the through silicon via 102 in the substrate 101, where the through silicon via 102 penetrates a first surface S1 and a second surface S2 of the substrate 101; and forming the buried power rail BPR and the device layer 103 sequentially on the second surface S2 of the substrate 101. Illustratively, the material of the substrate 101 may be monocrystalline silicon (Si), monocrystalline germanium (Ge), silicon germanium (GeSi), or silicon carbide (SiC), or may be silicon-on-insulator (SOI) or germanium-on-insulator (GOI), or may also be another material, for example, a group III-V compound, for example, gallium arsenide. The substrate 101 is patterned, and a conductive material is deposited in the substrate 101, to form the through silicon via 102. The through silicon via 102 penetrates the first surface S1 and the second surface S2 of the substrate 101; and the buried power rail BPR and the device layer 103 are further formed on the substrate with the formed through silicon via 102. In another embodiment, the device layer 103 and the buried power rail BPR may be formed first, and then the through silicon via 102 is formed. The sequence of formation is not limited herein. The device layer 103 may be formed with an active device, for example, a transistor or a diode; or a passive device, for example, a capacitor, an inductor, a resistor, and the like. The buried power rail BPR may also be formed within the substrate 101 as an interconnect line to which a power supply voltage or a grounding voltage is applied; and specifically, an opening may be formed by patterning the device layer 103 after the devices are formed in the device layer 103, depositing a conductive material therein, and performing chemical mechanical polishing.

In some embodiments, referring to FIG. 7, after the device layer 103 is formed within the substrate 101, the method further includes: forming a signal interconnect layer SL configured to connect the device layer 103 to an external control signal or an input/output signal on the device layer 103. The manufacturing of the signal interconnect layer SL may be completed by the damascene process to form a signal interconnect layer SL with alternate multi-layer metal and multi-layer dielectric materials. The material of the signal interconnect layer SL may include one or more of copper (Cu), nickel (Ni), cobalt (Co), tungsten (W), titanium (Ti), tin (Sn), or an alloy thereof.

In S200, a power network layer 104 and a capacitor structure 108 are formed on the substrate 101, where the power network layer 104 includes at least one layer of a first power array 1041 and at least one layer of a second power array 1042, each of the at least one layer of the first power array 1041 is connected to the buried power rail BPR through the through silicon via 102, and the capacitor structure 108 is formed between each of the at least one layer of the first power array 1041 and each of the at least one layer of the second power array 1042 and connected to the first power array 1041 and the second power array 1042 through a lower electrode 1081 and an upper electrode 1084 of the capacitor structure 108 respectively.

In some embodiments, referring to FIG. 2 to FIG. 4 and FIG. 8 to FIG. 13, the steps of forming the power network layer 104 and the capacitor structure 108 on the substrate 101 include:

In S210, the substrate 101 is provided with a first surface S1 and a second surface S2, an isolation layer 105 is formed on the first surface S1 of the substrate 101 through deposition, and the first power array 1041 is formed in the patterned isolation layer 105 through deposition, where the first power array 1041 extends along a first direction Y, and the first power array 1041 includes at least two power lines Vdd and at least two ground lines Vss. The process for depositing the isolation layer 105 includes, but is not limited to, chemical vapor deposition (chemical vapor deposition, CVD), physical vapor deposition (physical vapor deposition, PVD), atomic layer deposition (atomic layer deposition, ALD), electrochemical deposition (electrochemical deposition, ECD), and the material of the isolation layer 105 may be silicon oxide (SiO₂). The process for forming the first power array 1041 includes, but is not limited to, CVD, PVD, ALD, and ECD, and the material of the first power array 1041 may include one or more of copper (Cu), nickel (Ni), cobalt (Co), tungsten (W), titanium (Ti), tin (Sn), or an alloy thereof.

In S220, an insulating layer 106 is formed on the isolation layer 105 and the first power array 1041 through deposition, and the insulating layer 106 is patterned, where the patterned insulating layer 106 exposes a portion of the at least two power lines Vdd and the at least two ground lines Vss of the first power array 1041.

In S230, the capacitor structure 108, a contact plug CT, and the second power array 1042 are formed sequentially in the patterned insulating layer 106, where the second power array 1042 extends along a second direction X, the second power array 1042 includes at least two power lines Vdd and at least two ground lines Vss, and the first direction Y and the second direction X intersect in a direction parallel to the substrate 101. The angle formed by the intersection of the first direction Y and the second direction X in the direction parallel to the substrate 101 may be set to be a right angle, or other angles as needed. This is not limited herein. Projections of the first power array 1041 and the second power array 1042 in a direction perpendicular to the substrate 101 partially overlap, and the contact plug CT and the capacitor structure 108 are connected between the first power array 1041 and the second power array 1042. The power network layer 104 may be composed of the formed at least one first power array 1041 and at least one second power array 1042, and planes on which different power arrays are located are all parallel to the substrate 101 and are located at different layers. The second power array 1042 may be disposed above the first power array 1041, and the projections of the first power array 1041 and the second power array 1042 in the direction perpendicular to the substrate 101 share the overlapped portion.

In some embodiments, referring to FIG. 2 to FIG. 5 and FIG. 8 to FIG. 13, the insulating layer 106 includes a first blocking layer 1061, a first insulating layer 1062, a second blocking layer 1063, and a second insulating layer 1064, and forming the capacitor structure 108, the contact plug CT, and the second power array 1042 sequentially in the patterned insulating layer 106 includes:

In S2310, the first blocking layer 1061 and the first insulating layer 1062 are formed through deposition, and the first blocking layer 1061 and the first insulating layer 1062 are patterned, to form a first trench 107, where the first trench 107 exposes a portion of the power lines Vdd or the ground lines Vss of the first power array 1041.

In S2320, the lower electrode 1081, a dielectric layer 1082, a barrier layer 1083, and the upper electrode 1084 are formed sequentially from bottom to up within the first trench 107 through deposition, where the lower electrode 1081, the dielectric layer 1082, the barrier layer 1083, and the upper electrode 1084 form the capacitor structure 108, and the lower electrode 1081 is connected to each of the at least two power lines Vdd or each of the at least two ground lines Vss of the first power array 1041.

In S2330, the second blocking layer 1063 and the second insulating layer 1064 are formed through deposition, and the first blocking layer 1061, the first insulating layer 1062, the second blocking layer 1063, and the second insulating layer 1064 are patterned, to form a second trench 109, where the second trench 109 exposes a portion of the power lines Vdd or the ground lines Vss of the first power array 1041 and the upper electrode 1084 of the capacitor structure 108.

In S2340, a conductive material is deposited within the second trench 109 to form the contact plug CT and the second power array 1042. Illustratively, the deposition process for forming the first blocking layer 1061, the first insulating layer 1062, the second blocking layer 1063, and the second insulating layer 1064 includes, but is not limited to, CVD, PVD, and ALD, the deposition process for forming the lower electrode 1081, the dielectric layer 1082, the barrier layer 1083, and the upper electrode 1084 includes, but is not limited to, CVD, PVD, ALD, and ECD, and the patterning process may be dry etching or photomask etching. The materials of the first insulating layer 1062 and the second insulating layer 1063 may include silicon oxide (SiO₂), and the materials of the first blocking layer 1061 and the second blocking layer 1063 may include silicon nitride (SIN). The materials of the lower electrode 1081 and the upper electrode 1084 of the capacitor structure 108 may include cobalt (Co), titanium (Ti), nickel (Ni), tungsten (W), and molybdenum (Mo), metal nitride (for example, one or more of titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), and tungsten nitride (WN)). The material of the dielectric layer 1082 may include metal oxide (for example, one or more of HfO₂, ZrO₂, Al₂O₃, La₂O₃, Ta₂O₃, and TiO₂), and may have a single-layer structure or a multi-layer structure. The barrier layer 1083 may include metal nitride, for example, one or more of titanium nitride (TiN), titanium silicon nitride (TiSiN), titanium aluminum nitride (TiAlN), and tantalum nitride (TaN), tantalum silicon nitride (TaSiN), tantalum aluminum nitride (TaAlN), and tungsten nitride (WN).

In some embodiments, the lower electrode 1081 of the capacitor structure 108 is connected to each of the power lines Vdd of the first power array 1041, and the upper electrode 1084 of the capacitor structure 108 is connected to each of the ground lines Vss of the second power array 1042; or the lower electrode 1081 of the capacitor structure 108 is connected to each of the ground lines Vss of the first power array 1041, and the upper electrode 1084 of the capacitor structure 108 is connected to each of the power lines Vdd of the second power array 1042.

In some embodiments, the contact plug CT is configured to connect each of the power lines Vdd of the first power array 1041 to each of the power lines Vdd of the second power array 1042, or connect each of the ground lines Vss of the first power array 1041 to each of the ground lines Vss of the second power array 1042.

In some embodiments, the semiconductor structure 10 may include a memory device. For example, the memory device may be a non-volatile memory device, for example, at least one of a flash memory, a phase change random access memory (PRAM), a magnetoresistive random access memory (MRAM), a ferroelectric random access memory (FeRAM), and a resistive random access memory (RRAM). For example, the flash memory includes a NAND flash memory or a V-NAND flash memory. In some embodiments, the memory device includes a volatile memory device, for example, a dynamic random access memory (DRAM) or a static random access memory (SRAM). The memory semiconductor chip includes a semiconductor device, and the semiconductor device includes a plurality of standalone devices of various types. The plurality of standalone devices include various types of microelectronic devices such as a metal oxide semiconductor field effect transistor (MOSFET) including a CMOS transistor, a large scale integration (LSI) circuit, an active device, or a passive device.

In summary, according to the embodiments of the present disclosure, the capacitor structure is integrated into an internal part of the power delivery network, and the voltage stabilization can be improved without adding an additional capacitor structure, such that the volume of a chip is reduced; moreover, as the internal part of the power network can be directly connected to the capacitor structure, a power delivery path is shortened, such that the transmission resistance is reduced, and the stability and reliability of the power network are further enhanced.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

What is claimed is:

1. A semiconductor structure, comprising:
a substrate, comprising a device layer, a buried power rail, and a through silicon via, wherein the through silicon via is connected to the device layer through the buried power rail;
a power network layer, disposed on the substrate, wherein the power network layer comprises at least one layer of a first power array and at least one layer of a second power array, and each of the at least one layer of the first power array is connected to the buried power rail through the through silicon via; and
a capacitor structure, disposed between each of the at least one layer of the first power array and each of the at least one layer of the second power array and connected to the first power array and the second power array through a lower electrode and an upper electrode of the capacitor structure respectively.

2. The semiconductor structure according to claim 1, wherein the first power array extends along a first direction, the second power array extends along a second direction, the first direction and the second direction intersect in a direction parallel to the substrate, and projections of the first power array and the second power array in a direction perpendicular to the substrate share overlapped portions.

3. The semiconductor structure according to claim 2, wherein the first power array and the second power array each comprise at least two power lines and at least two ground lines, the at least two power lines and the at least two ground lines of the first power array are parallel to one another and staggered along the second direction, and the at least two power lines and the at least two ground lines of the second power array are parallel to one another and staggered along the first direction.

4. The semiconductor structure according to claim 3, wherein the overlapped portions of the projections of the first power array and the second power array in the direction perpendicular to the substrate comprises at least one first region and at least one second region, the at least one first region comprises overlapped portions of projections of the power lines of the first power array and the power lines of the second power array in the direction perpendicular to the substrate and overlapped portions of projections of the ground lines of the first power array and the ground lines of the second power array in the direction perpendicular to the substrate; and
the at least one second region comprises overlapped portions of projections of the ground lines of the first power array and the power lines of the second power array in the direction perpendicular to the substrate and overlapped portions of projections of the power lines of the first power array and the ground lines of the second power array in the direction perpendicular to the substrate.

5. The semiconductor structure according to claim 4, wherein a contact plug is further provided between the first power array and the second power array, and the contact plug is disposed in each of the at least one first region and configured to connect each of the power lines of the first power array to each of the power lines of the second power array, or connect each of the ground lines of the first power array to each of the ground lines of the second power array.

6. The semiconductor structure according to claim 4, wherein the capacitor structure is disposed in each of the at least one second region, the lower electrode of the capacitor structure is connected to each of the power lines of the first power array, and the upper electrode of the capacitor structure is connected to each of the ground lines of the second power array; or the lower electrode of the capacitor structure is connected to each of the ground lines of the first power array, and the upper electrode of the capacitor structure is connected to each of the power lines of the second power array.

7. The semiconductor structure according to claim 3, wherein the power lines and the ground lines of the first power array are of a same quantity, and the power lines and the ground lines of the second power array are of a same quantity.

8. The semiconductor structure according to claim 7, wherein a distance between each of the power lines and each of the ground lines that are adjacent to one another ranges from 0.1 μm to 1.5 μm.

9. A method for manufacturing a semiconductor structure, comprising:
providing a substrate, wherein a device layer, a buried power rail, and a through silicon via are formed within the substrate, and the through silicon via is connected to the device layer through the buried power rail; and
forming a power network layer and a capacitor structure on the substrate, wherein the power network layer comprises at least one layer of a first power array and at least one layer of a second power array, each of the at least one layer of the first power array is connected to the buried power rail through the through silicon via, and the capacitor structure is formed between each of the at least one layer of the first power array and each of the at least one layer of the second power array and connected to the first power array and the second power array through a lower electrode and an upper electrode of the capacitor structure respectively.

10. The method according to claim 9, wherein steps of forming the power network layer and the capacitor structure on the substrate comprise:
providing the substrate with a first surface and a second surface, forming an isolation layer on the first surface of the substrate, and forming the first power array in a patterned isolation layer, wherein the first power array extends along a first direction, and the first power array comprises at least two power lines and at least two ground lines;
forming an insulating layer on the isolation layer and the first power array through deposition, and patterning the insulating layer, wherein a patterned insulating layer exposes a portion of the at least two power lines and the at least two ground lines of the first power array; and
forming the capacitor structure, a contact plug, and the second power array sequentially in the patterned insulating layer, wherein the second power array extends along a second direction, the second power array comprises at least two power lines and at least two ground lines, the first direction and the second direction intersect in a direction parallel to the substrate, projections of the first power array and the second power array in a direction perpendicular to the substrate partially overlap, and the contact plug and the capacitor structure are connected between the first power array and the second power array.

11. The method according to claim 10, wherein the lower electrode of the capacitor structure is connected to each of the at least two power lines of the first power array, and the upper electrode of the capacitor structure is connected to each of the at least two ground lines of the second power array; or the lower electrode of the capacitor structure is connected to each of the at least two ground lines of the first power array, and the upper electrode of the capacitor structure is connected to each of the at least two power lines of the second power array.

12. The method according to claim 10, wherein the contact plug is configured to connect each of the at least two power lines of the first power array to each of the at least two power lines of the second power array, or connect each of the at least two ground lines of the first power array to each of the at least two ground lines of the second power array.

13. The method according to claim 10, wherein the insulating layer comprises a first blocking layer, a first insulating layer, a second blocking layer, and a second insulating layer, and forming the capacitor structure, the contact plug, and the second power array sequentially in the patterned insulating layer comprises:
forming the first blocking layer and the first insulating layer through deposition, and patterning the first blocking layer and the first insulating layer, to form a first trench, wherein the first trench exposes a portion of the power lines or the ground lines of the first power array;
forming the lower electrode, a dielectric layer, a barrier layer, and the upper electrode sequentially within the first trench through deposition, wherein the lower electrode, the dielectric layer, the barrier layer, and the upper electrode form the capacitor structure, and the lower electrode is connected to each of the at least two power lines or each of the at least two ground lines of the first power array;
forming the second blocking layer and the second insulating layer through deposition, and patterning the first blocking layer, the first insulating layer, the second blocking layer, and the second insulating layer, to form a second trench, wherein the second trench exposes a portion of the power lines or the ground lines of the first power array and the upper electrode of the capacitor structure; and
depositing a conductive material within the second trench to form the contact plug and the second power array.

14. The method according to claim 10, wherein forming the device layer, the buried power rail, and the through silicon via within the substrate comprises:
forming the through silicon via in the substrate, wherein the through silicon via penetrates the first surface and the second surface of the substrate; and
forming the buried power rail and the device layer sequentially on the second surface of the substrate.

15. The method according to claim 14, wherein after the device layer is formed within the substrate, the method further comprises: forming a signal interconnect layer on the device layer.
